(19) United States
(12) Patent Application Publication
(10) Pub. No.: US 2023/0259016 A1
(43) Pub. Date: Aug. 17, 2023

(54) SYSTEM, METHOD AND PROGRAM PRODUCT FOR IMPROVING ACCURACY OF PHOTOMASK BASED COMPENSATION IN FLAT PANEL DISPLAY LITHOGRAPHY

(71) Applicant: PHOTRONICS, INC., BROOKFIELD, CT (US)

(72) Inventors: Christopher Progler, Plano, TX (US); Young Mog Ham, Meridian, ID (US)

(21) Appl. No.: 18/109,589

(22) Filed: Feb. 14, 2023

Related U.S. Application Data
(60) Provisional application No. 63/268,144, filed on Feb. 17, 2022.

(51) Int. Cl. G03F 1/36; G03F 1/26; G03F 1/54

(52) U.S. Cl. CPC G03F 1/36; G03F 1/26; G03F 1/54

(57) ABSTRACT

A method of manufacturing a photomask including determining based on initial photomask design data a first contour associated with at least one pattern expected to result from writing of the photomask and determining based on the first contour a second contour associated with the at least one pattern expected to result from etching of the written photomask. The second contour is an expected actual contour of the at least one pattern. The initial photomask data is optical proximity corrected using the second contour to generate corrected photomask design data. In embodiments, a photomask blank is provided with at least three layers and the blank is processed in accordance with the corrected photomask design data to minimize etch skew effects.

### RELATED APPLICATIONS

This application claims priority to and the benefit of U.S. Provisional Application No. 63/268,144, file Feb. 17, 2022 and entitled SYSTEM, METHOD AND PROGRAM PRODUCT FOR IMPROVIING ACCURACY OF PHOTOMASK BASED COMPENSATION IN FLAT PANEL DISPLAY LITHOGRAPHY, the contents of which are incorporated herein by reference in their entirety.

### FIELD OF THE INVENTION

The present invention generally relates to manufacturing of photomasks, and more particularly to photomask manufacturing correction techniques used in flat panel display (FPD) lithography.

### BACKGROUND

Photomask technology has contributed to the capability and productivity of integrated circuit (IC) and flat panel display (FPD) manufacturing, including the implementation of masks which improve process capability, margins and yield. Such masks include, for example, advanced binary or multi-tone masks and phase shifting masks, to name a few. These masks are mainly composed of a transparent substrate and absorbing (e.g., CrOx, CrON) and phase shift films (e.g., MoSi, SiN) that are patterned to deliver and sustain the optical, physical and mechanical requirements of the mask. Therefore, in mask fabrication, the optimum mask process condition and its controllability to process those films impacts patterning quality and performance of the mask in the lithography process.

Furthermore, the lithography process in FPD determines the capability and output capacity of flat panel products. Generally, the panel device patterns and various shapes and proximity effects of those patterns on the photomask affect the lithography quality when the light passes through the mask and is imaged onto the panel substrate by the exposing lithography tool. The exposing tool acts as a low pass filter and thus it can reduce the fidelity and quality of the transferred panel device patterns on mask during imaging. To compensate for this image fidelity loss, various mask correction methods have been used to improve the fidelity of the printed mask images for integrated circuit applications. For example, the use selective feature biassing and optical proximity correction or OPC were introduced in IC manufacturing and have now become a routine action to apply these adjustments or corrections to the mask patterns to compensate for the lithographic imaging process.

However, for the FPD panel process, the design and processes are very different from conventional IC products and require special dedicated solutions. For example, leading edge panel product designs have much larger dimension features patterned over much larger areas and the families of shapes of such features are often different compared to advanced IC designs. Most importantly, the photomasks used in even the most advanced FPD lithography processes are built only using laser-based mask writing and wet chemical etching as opposed to the higher resolution electron beam writing and dry etching methods prevalent in advanced IC masks. Consequently, the techniques routinely deployed in IC lithography such as selective feature bias or optical proximity correction which are so impactful in IC are much less effective when used in flat panel lithography because these methods rely on the fundamentally higher performing mask making process in IC which does not exist for flat panel mask making. For this reason, a new total correction method is needed which is applicable to the special needs of flat panel mask making and also lithography for the advanced flat panel display applications.

### SUMMARY OF THE INVENTION

In exemplary embodiments, systems and methods in accordance with this invention combine critical techniques of mask pattern shape manipulation, mask blank properties and mask manufacturing to a create a correction system ideally optimized for masks used to benefit FPD lithography. In embodiments, the techniques may be used individually or in combination to induce the optimal correction.

In accordance with an exemplary embodiment of the present invention, a method of manufacturing a photomask comprises: receiving initial photomask design data associated with one or more patterns to be formed on a photomask; determining based on the initial photomask design data a first contour associated with at least one of the one or more patterns expected to result from writing of the photomask; determining based on the first contour a second contour associated with the at least one of the one or more patterns expected to result from etching of the written photomask, where the second contour is an expected actual contour of the at least one of the one or more patterns; performing, using the second contour associated with the at least one of the one or more patterns, optical proximity correction to the initial photomask data; and generating corrected photomask design data based on the optical proximity corrected initial photomask design data.

In exemplary embodiments the step of determining a first contour is performed using a smoothing model.

In exemplary embodiments the smoothing model is a Gaussian model.

In exemplary embodiments the step of determining a second contour is performed by determining propagation vectors extending from the first contour.

In exemplary embodiments the propagation vectors are based on at least one of etch skew and etch process parameters.

In exemplary embodiments the method further comprises the step of providing a mask blank comprising at least three layers disposed over a substrate.

In exemplary embodiments the method further comprises the step of processing the mask blank using the corrected photomask design data to form a photomask for use in a lithography process.

In exemplary embodiments the photomask is a large-size photomask for use in a lithography process to manufacture a flat panel display (FPD).

In exemplary embodiments the photomask blank comprises: a substrate; a first layer disposed over the substrate that is a phase shift layer; a second layer disposed over the first layer that is an etch stop layer; and a third layer disposed over the second layer that is an absorber layer.

In exemplary embodiments the step of processing the mask blank comprises: exposing and developing a first photoresist disposed over the third layer so as form a pattern of exposed portions of the third layer; etching the exposed portions of the third layer so as to form a pattern of exposed portions of the second layer; etching the exposed portions of the second layer so as to form a pattern of exposed portions of the first layer; depositing a second photoresist over the first layer, the etched second layer, and the etched third layer; exposing and developing the second photoresist so as to form a pattern of exposed portions of the first layer; and etching the exposed portions of the first layer so as to form a pattern of exposed portions of the substrate.

In exemplary embodiments the first layer comprises Cr.

In exemplary embodiments the second layer comprise MoSi.

In exemplary embodiments the third layer comprises Cr.

In accordance with an exemplary embodiment of the present invention, a method of manufacturing a photomask comprising two or more of the following steps (A), (B) and (C):

(A) generating a photomask pattern design, the step of generating comprising: (1) receiving initial photomask design data associated with one or more patterns to be formed on a photomask; (2) determining based on the initial photomask design data a first contour associated with at least one of the one or more patterns expected to result from writing of the photomask; (3) determining based on the first contour a second contour associated with the at least one of the one or more patterns expected to result from etching of the written photomask, where the second contour is an expected actual contour of the at least one of the one or more patterns; (4) performing, using the second contour associated with the at least one of the one or more patterns, optical proximity correction to the initial photomask data; and (5) generating corrected photomask design data based on the optical proximity corrected initial photomask design data; (B) providing a mask blank comprising at least three layers disposed over a substrate; and (C) processing a mask blank comprising a substrate, a first layer disposed over the substrate that is a phase shift layer, a second layer disposed over the first layer that is an etch stop layer, and a third layer disposed over the second layer that is an absorber layer, the step of processing comprising: (1) exposing and developing a first photoresist disposed over a third layer so as form a pattern of exposed portions of the third layer; (2) etching the exposed portions of the third layer so as to form a pattern of exposed portions of the second layer; (3) etching the exposed portions of the second layer so as to form a pattern of exposed portions of the first layer; (4) depositing a second photoresist over the first layer, the etched second layer, and the etched third layer; (5) exposing and developing the second photoresist so as to form a pattern of exposed portions of the first layer; and (6) etching the exposed portions of the first layer so as to form a pattern of exposed portions of the substrate.

In exemplary embodiments the method comprises steps (A) and (B).

In exemplary embodiments the method comprises steps (A), (B) and (C).

In exemplary embodiments the photomask is a large-size photomask for use in a lithography process to manufacture a flat-panel display (FPD).

In accordance with exemplary embodiments of the present invention, a method of making a flat panel display comprises irradiating light from an optical energy source through a large-size photomask made in accordance with the method of claim 14 and onto a glass plate substrate in a photolithographic process so that the at least one circuit pattern is transferred from the large-size photomask to the glass plate substrate.

In exemplary embodiments the flat-panel display is a liquid crystal display, an active matrix liquid crystal display, an organic light emission diode, a light emitting diode, a plasma display panel, or an active matrix organic light emission diode.

These and other features and advantages of the present invention will be presented in more detail in the following detailed description and the accompanying figures which illustrate by way of example principles of the invention.

### DESCRIPTION OF THE DRAWINGS

Various exemplary embodiments of this invention will be described in detail, with reference to the following figures, wherein:

FIG. 1 is a cross section of a conventional manufactured FPD mask showing etch skew;

FIG. 2 is a simplified block diagram of an embodiment of a flat panel display (FPD) manufacturing system and an FPD manufacturing flow associated therewith, in accordance with an exemplary embodiment of the present invention;

FIG. 3 3 illustrates a schematic diagram of an exemplary mask enhancer system for enhancing photo mask layouts in accordance with an exemplary embodiment of the present invention;

FIG. 4 is a block diagram of a computer system pertaining to a mask enhancer system in accordance with an exemplary embodiment of the present invention;

FIGS. 5A-5C illustrate different degrees of pattern correction that can be made to a photomask;

FIG. 6 shows components of skew driven mismatch between desired mask shape and desired feature;

FIG. 7 shows a propagation vector originating from a point on a Gaussian type contour with a terminal point on a real mask pattern contour resulting from etching skew in accordance with an exemplary embodiment of the present invention;

FIG. 8 shows a process for mask design correction in accordance with an exemplary embodiment of the present invention;

FIGS. 9A-9E show cross sections of several types of masks, including materials and stacking sequence, with FIG. 9D showing a cross section in accordance with an exemplary embodiment of the present invention; and

FIGS. 10A-10I illustrate a mask making flow in accordance with an exemplary embodiment of the present invention that minimizes the skew parameters in a three-film stack.

### DETAILED DESCRIPTION

Flat-panel displays (FPDs) are electronic viewing technologies used to display content (e.g., still images, moving images, text, or other visual material) in a range of entertainment, consumer electronic, personal computer, and mobile devices, and many types of medical, transportation and industrial equipment. The current FPD types include, for example, LCD (Liquid Chrystal Display), AM LCD (Active Matrix Liquid Chrystal Display), OLED (Organic Light Emission Diode), LED (Light Emitting Diode), PDP (Plasma Display Panel) and AMOLED (Active Matrix OLED).

During manufacture of an FPD, an FPD lithography system irradiates light onto a photomask on which the original thin-film-transistor (TFT) circuit patterns are drawn, and the light exposes the patterns onto a glass plate substrate through a lens. On a large glass plate, the exposure process is repeated several times in order to form the patterns onto the entire plate.

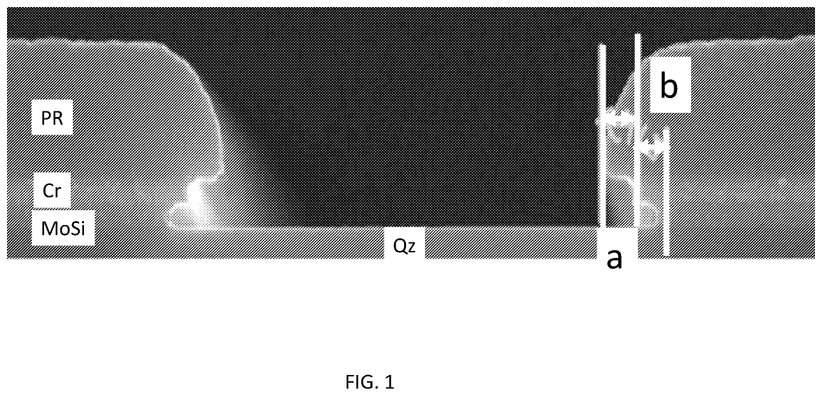

Applying optical proximity correction or feature bias requires the edges of the mask feature to be adjusted to have the printed mask feature most closely match the corrected design feature when the mask prints on the flat panel display substrate by the lithography scanner. To accurately reproduce the mask feature edge adjustments the mask blank and process combination must be inherently one of low bias or skew. That is, if the edge needs to be adjusted by amount X on the mask pattern to meet the needs of the mask pattern correction scheme but the mask blank and process cannot reproduce the amount X due to a high skew or high bias mask process of Y then the mask correction will be less effective or in worst case totally ineffective or counterproductive. FIG. 1 shows the cross section of a manufactured FPD mask to illustrate this important point, where Y=a+b. To the extent Y overwhelms and/or misrepresents the desired mask edge correction amount X then the optimum correction method will not be possible.

Consequently, in order to achieve the optimum benefit from the mask pattern correction scheme, exemplary embodiments of the present invention may employ at least one of three elements to deliver a superior FPD mask correction performance that optimizes panel lithography. In embodiments, the three elements include the following:

1. An algorithm optimized for high skew nature of the mask making in FPD applications (“Element 1”).

2. A mask making blank that minimizes the skew level with structural film compositions (“Element 2”).

3. A mask etching process that minimizes the skew level with process etching parameters (“Element 3”).

In exemplary embodiments, each of these elements may be employed independently in the formation of an optimized mask correction system, or alternatively two or more of these elements may be employed together as part of an overall mask correction system. In a specific exemplary embodiment, all three of the elements are employed together.

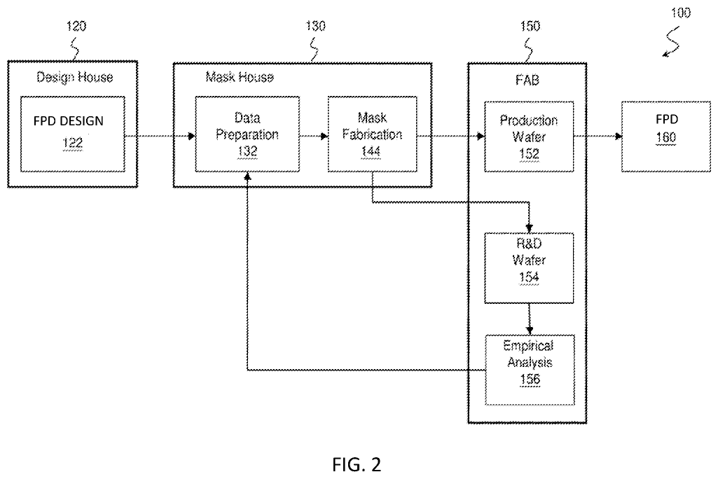

FIG. 2 is a simplified block diagram of an embodiment of a flat panel display (FPD) manufacturing system 100 and an FPD manufacturing flow associated therewith, in accordance with an exemplary embodiment of the present invention. The FPD manufacturing system 100 includes a plurality of entities, such as a design house 120, a mask house 130, and an FPD manufacturer 150 (i.e., a fab), that interact with one another in the design, development, and manufacturing cycles and/or services related to manufacturing an FPD device 160. The plurality of entities may be connected by a communications network, which may be a single network or a variety of different networks, such as an intranet and the Internet, and may include wired and/or wireless communication channels. Each entity may interact with other entities and may provide services to and/or receive services from the other entities. In embodiments, one or more of the design house 120, mask house 130, and FPD manufacturer 150 may have a common owner, and may even coexist in a common facility and use common resources.

In various embodiments, the design house 120, which may include one or more design teams, generates an FPD design layout 122. The FPD design layout 122 may include various geometrical patterns designed for the fabrication of the FPD device 160. By way of example, the geometrical patterns may correspond to patterns of metal, oxide, or semiconductor layers that make up the various components of the FPD device 160 to be fabricated. The various layers combine to form various features of the FPD device 160, such as, for example, thin film transistors (TFTs). For example, various portions of the FPD design layout 122 may include features such as an active region, a gate electrode, source and drain regions, metal lines or vias of a metal interconnect, openings for bond pads, as well as other features known in the art which are to be formed on an FPD glass substrate and various material layers disposed on the glass substrate. In exemplary embodiments, the design house 120 implements a design procedure to form the FPD design layout 122. The design procedure may include logic design, physical design, and/or place and route. The FPD design layout 122 may be presented in one or more data files having information related to the geometrical patterns which are to be used for fabrication of the FPD device 160. In embodiments, the FPD design layout 122 may be expressed in various formats, such as, for example, an Open Artwork System Interchange Standard (OASIS) file format, a GDSII file format, or DFII file format, to name a few.

In embodiments, the design house 120 may transmit the FPD design layout 122 to the mask house 130, for example, via the network connection described above. The mask house 130 may then use the FPD design layout 122 to manufacture one or more masks to be used for fabrication of the various layers of the FPD device 160 according to the FPD design layout 122. In various examples, the mask house 130 performs mask data preparation 132, where the FPD design layout 122 is translated into a form that can be physically written by a mask writer, and mask fabrication 144, where the design layout prepared by the mask data preparation 132 is modified to comply with a particular mask writer and/or mask manufacturer and is then fabricated. In the example of FIG. 2, the mask data preparation 132 and mask fabrication 144 are illustrated as separate elements; however, in some embodiments, the mask data preparation 132 and mask fabrication 144 may be collectively referred to as mask data preparation.

In embodiments, the mask data preparation 132 includes application of one or more resolution enhancement technologies (RETs) to compensate for potential lithography errors, such as those that can arise from diffraction, interference, or other process effects. In embodiments, optical proximity correction (OPC) may be used to adjust line widths depending on the density of surrounding geometries, add “dog-bone” end-caps to the end of lines to prevent line end shortening, correct for electron beam (e-beam) proximity effects, or for other purposes. For example, OPC techniques may add sub-resolution assist features (SRAFs), which for example may include adding scattering bars, serifs, and/or hammerheads to the FPD design layout 122 according to optical models or rules such that, after a lithography process, a final pattern on a glass substrate is improved with enhanced resolution and precision. The mask data preparation 132 may also include further RETs, such as off-axis illumination (OAI), phase-shifting masks (PSM), other suitable techniques, or combinations thereof.

In embodiments, the mask data preparation 132 may include a mask process correction (MPC) that is used to correct errors introduced during the mask making process. For example, the MPC may be used to correct mask making process effects such as fogging, development and etch loading and e-beam proximity effects. In embodiments, the MPC process modifies a post-OPC design layout to compensate for limitations which may be encountered during mask fabrication 144.

In embodiments, the mask data preparation 132 may include lithography process checking (LPC) that simulates processing that will be implemented by the FPD manufacturer 150 to fabricate the FPD device 160. The LPC may simulate this processing based on the FPD design layout 122 to create a simulated manufactured device, such as the FPD device 160. The processing parameters in LPC simulation may include parameters associated with various processes of the FPD manufacturing cycle, parameters associated with tools used for manufacturing the FPD, and/or other aspects of the manufacturing process. By way of example, LPC may take into account various factors, such as aerial image contrast, depth of focus (DOF), mask error enhancement factor (MEEF), other suitable factors, or combinations thereof.

In embodiments, after a simulated manufactured device has been created by LPC, if the simulated device layout is not close enough in shape to satisfy design rules, certain steps in the mask data preparation 132, such as OPC and MPC, may be repeated to refine the IC design layout 122 further.

It should be understood that the above description of the mask data preparation 132 has been simplified for the purposes of clarity, and data preparation may include additional features such as a logic operation (LOP) to modify the FPD design layout according to manufacturing rules. Additionally, the processes applied to the FPD design layout 122 during data preparation 132 may be executed in a variety of different orders.

After mask data preparation 132 and during mask fabrication 144, a mask or a group of masks may be fabricated based on the modified FPD design layout. In embodiments, an electron-beam (e-beam) or a mechanism of multiple e-beams is used to form a pattern on a mask (photomask or reticle) based on the modified FPD design layout. In embodiments, a mask pattern includes opaque regions and transparent regions. A radiation beam, such as an ultraviolet (UV) beam, used to expose a radiation-sensitive material layer (e.g., photoresist) coated on a wafer, is blocked by the opaque region and transmitted through the transparent regions. In embodiments, a binary mask includes a transparent substrate (e.g., fused quartz) and an opaque material (e.g., chromium) coated in the opaque regions of the mask. In embodiments, the mask is formed using a phase shift technology. In a phase shift mask (PSM), various features in the pattern formed on the mask are configured to have a pre-configured phase difference to enhance image resolution and imaging quality. In embodiments, the phase shift mask can be an attenuated PSM or alternating PSM.

In embodiments, the FPD manufacturer 150 may use the mask (or masks) fabricated by the mask house 130 to transfer one or more mask patterns onto a production glass substrate 152 and thus fabricate the FPD device 160 on the production glass substrate 152. The FPD manufacturer 150 may include an FPD fabrication facility that may include a myriad of manufacturing facilities for the fabrication of a variety of different FPD products. For example, the FPD manufacturer 150 may include a first manufacturing facility for front end fabrication of a plurality of FPD products (i.e., front-end-of-line (FEOL) fabrication), while a second manufacturing facility may provide back end fabrication for the interconnection and packaging of the FPD products (i.e., back-end-of-line (BEOL) fabrication), and a third manufacturing facility may provide other services. In various embodiments, the production FPD 152 within and/or upon which the FPD device 160 is fabricated may include a glass substrate, where the glass type may be, for example, aluminosilicate glass, borosilicate glass, or fused silica, to name a few. In embodiments, a large-size photomask may be appropriately sized to accommodate photolithography processing of glass plate substrates used to form FPDs.

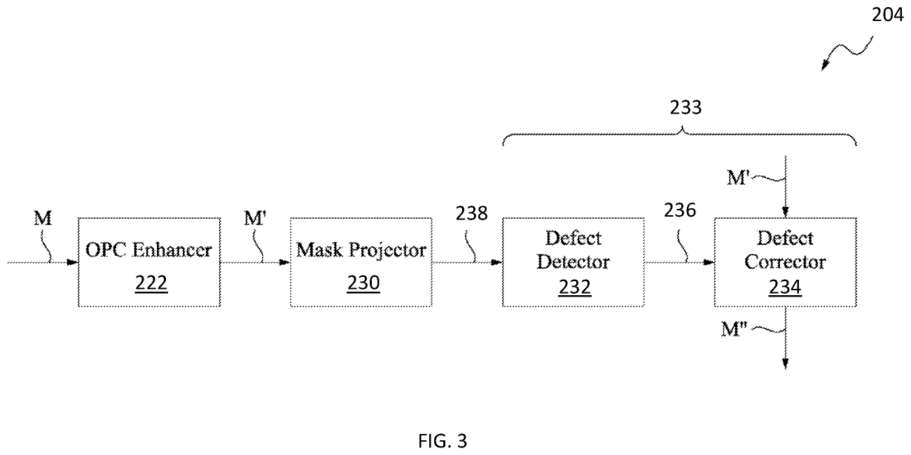

In exemplary embodiments, mask data preparation may involve the use of a mask enhancer system. In this regard, FIG. 3 illustrates a schematic diagram of an exemplary mask enhancer system 204 for enhancing photo mask layouts in accordance with some embodiments. Some embodiments of mask enhancer system 204 include an OPC enhancer 222 that receives the mask layout M that is produced by the design house 120 and produces the OPCed (e.g., the corrected) mask layout M. As described, OPC is a lithography technique that is used to correct or enhance the mask layout M, and produce improved imaging effects to reproduce, on the glass substrate, the original layout drawn by the FPD design house 120. For example, OPC can be used to compensate for imaging distortions due to optical diffraction. In some embodiments, the mask layout M is a data file having the information of the geometrical patterns to be produced on the substrate, and the OPC enhancer 222 modifies the data file and produces a corrected data file representing a corrected mask layout M′.

In exemplary embodiments, a mask projector 230 may be applied on the corrected mask layout M to produce a projected mask layout 238 on the wafer. In some embodiments, corrected mask layout M is a data file and the mask projector 230 simulates the projection of the corrected mask layout M′ on the wafer and produces the simulated projected mask layout 238. The defect detector 232 of the mask enhancer 204 inspects the projected mask layout 238 and finds the defective areas 236 of the projected mask layout 238. Although the corrected mask layout M′ is OPCed, defective areas may be produced when the corrected mask layout M′ is projected on the substrate 208.

In embodiments, a defect corrector 234 of the mask enhancer 204 may receive the defective areas 236 and the corrected mask layout M′ and implement further correction, e.g., enhancement, on the corrected mask layout M′, thereby producing the enhanced mask layout M″. In embodiments, defect detector 232 may be combined into the defect corrector 234 creating a layout detection and correction system 233 that receives the projected mask layout 238 and the corrected mask layout M′ and provides the enhanced mask layout M″.

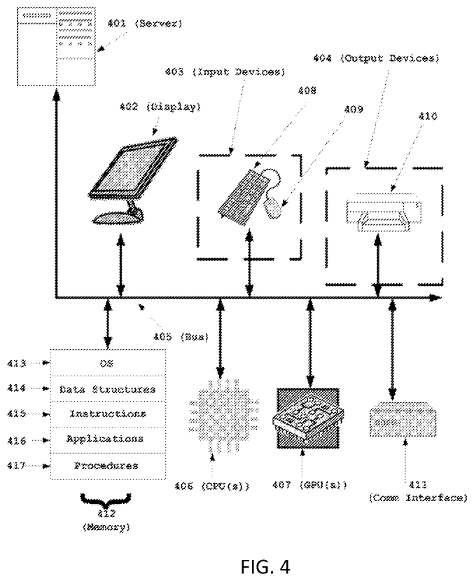

In exemplary embodiments, the mask enhancer system 204 may include specialized hardware components, software components, and/or combinations of both hardware and software components to carry out the various procedures related to enhancement and correction of a photomask as part of an FPD manufacturing process. In this regard, FIG. 4 depicts an illustrative computer system pertaining to a mask enhancer system in accordance with various embodiments of the present invention. In some embodiments, the computer system includes a server 401, display 402, one or more input interfaces 403, and one or more output interfaces 404, all conventionally coupled by one or more buses 405. Examples of suitable buses include, for example, PCI-Express®, AGP, PCI, ISA, and the like, to name a few.

The computer system may include any number of graphics processors. The graphics processor may reside on a motherboard such as being integrated with a motherboard chipset. One or more graphics processors may reside on external boards connected to the system through a bus such as an ISA bus, PCI bus, AGP port, PCI Express, or other system buses, to name a few. Graphics processors may on separate boards, each connected to a bus such as the PCI Express bus to each other and to the rest of the system. Further, there may be a separate bus or connection (e.g., Nvidia SLI or ATI CrossFire connection, to name a two) by which the graphics processors may communicate with each other. This separate bus or connection may be used in addition to or in substitution for system bus.

The server 401 may include one or more CPUs 406, one or more GPUs 407, and one or more memory modules 412. Each CPU and GPU may be a single core or multiple core unit. Examples of suitable CPUs include Intel Pentium®, Intel Core™ 2 Duo, AMD Athlon 64, AMD Opteron®, and the like, to name a few. Examples of suitable GPUs include Nvidia GeForce®, ATI Radeon®, and the like, to name a few. The input interfaces 403 may include a keyboard 408 and a mouse 409. The output interface 404 may include a printer 410.

In embodiments, the communications interface 411 is a network interface that allows the computer system to communicate via a wireless or hardwired network. The communications interface 411, may be coupled to a transmission medium (not shown), such as a network transmission line, for example, twisted pair, coaxial cable, fiber optic cable, and the like, to name a few. In another embodiment, the communications interface 411, provides a wireless interface, that is, the communication interface 411 uses a wireless transmission medium. Examples of other devices that may be used to access the computer system via communications interface 411 include cell phones, PDAs, personal computers, and the like (not shown), to name a few.

The memory modules 412 may generally include different modalities, illustratively semiconductor memory, such as random access memory (RAM), and disk drives as well as others. In various embodiments, the memory modules 412 store an operating system 413, data structures 414, instructions 415, applications 416, and procedures 417.

Storage devices may include mass disk drives, floppy disks, magnetic disks, optical disks, magneto-optical disks, fixed disks, hard disks, CD-ROMs, recordable CDs, DVDs, recordable DVDs (e.g., DVD-R, DVD+R, DVD-RW, DVD+RW, HD-DVD, or Blu-ray Disc), flash and other nonvolatile solid-state storage (e.g., USB flash drive), battery-backed-up volatile memory, tape storage, reader, and other similar media, and combinations of these.

In various embodiments, the specific software instructions, data structures, and data that implement various embodiments of the present invention are typically incorporated in the server 401. Generally, an embodiment of the present invention is tangibly embodied using a computer readable medium, for example, the memory, and includes of instructions, applications, and procedures which, when executed by the processor, causes the computer system to utilize the present invention, for example, the collection and analysis of data, pixelating structures, determining edge placement errors, moving edge fragments, optimizing edge fragment placements, and the like. The memory may store the software instructions, data structures, and data for any of the operating system, the data collection application, the data aggregation application, the data analysis procedures, and the like in semiconductor memory, in disk memory, or a combination of these.

A computer-implemented or computer-executable version of the invention may be embodied using, stored on, or associated with computer-readable medium. A computer-readable medium may include any medium that participates in providing instructions to one or more processors for execution. Such a medium may take many forms including, but not limited to, nonvolatile, volatile, and transmission media. Nonvolatile media includes, for example, flash memory, or optical or magnetic disks. Volatile media includes static or dynamic memory, such as cache memory or RAM. Transmission media includes coaxial cables, copper wire, fiber optic lines, and wires arranged in a bus. Transmission media can also take the form of electromagnetic, radio frequency, acoustic, or light waves, such as those generated during radio wave and infrared data communications.

For example, a binary, machine-executable version, of the software of the present invention may be stored or reside in RAM or cache memory, or on a mass storage device. The source code of the software of the present invention may also be stored or reside on mass storage device (e.g., hard disk, magnetic disk, tape, or CD-ROM). As a further example, code of the invention may be transmitted via wires, radio waves, or through a network such as the Internet.

The operating system may be implemented by any conventional operating system comprising Windows® (registered trademark of Microsoft Corporation), Unix® (registered trademark of the Open Group in the United States and other countries), Mac OS® (registered trademark of Apple Computer, Inc.), Linux® (registered trademark of Linus Torvalds), as well as others not explicitly listed here.

In various embodiments, the present invention may be implemented as a method, system, or article of manufacture using standard programming or engineering techniques, or both, to produce software, firmware, hardware, or any combination thereof. The term “article of manufacture” (or alternatively, “computer program product”) as used in this application is intended to encompass a computer program accessible from any computer readable device, carrier or media. In addition, the software in which various embodiments are implemented may be accessible through the transmission medium, for example, from a server over the network. The article of manufacture in which the code is implemented also encompasses transmission media, such as the network transmission line and wireless transmission media. Thus the article of manufacture also includes the medium in which the code is embedded. Those skilled in the art will recognize that many modifications may be made to this configuration without departing from the scope of the present invention.

The computer system illustrated in FIG. 4 is not intended to limit the present invention. Other alternative hardware and/or software environments may be used without departing from the scope of the present invention.

For FPD mask making, the pattern correction algorithm for feature bias and compensation must account for the high skew nature of the mask making process. Specifically, the mask making process involves a step of laser writing and a step of etching. As described above with reference to FIG. 1, inconsistent or undesirable patterns may result from the etching step due to high skew. In embodiments, Element 1 applies a more accurate and practical model to express panel design layout and features in the panel mask process. When applied in simulation, panel OPC and any other prediction S/W, the Element 1 model can more accurately predict the result in the process and manufacturing.

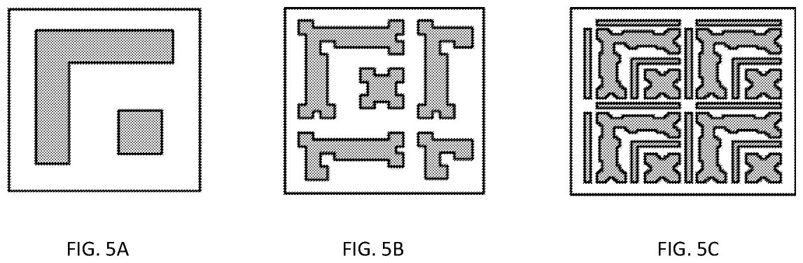

As shown in FIGS. 5A-5C, different degrees of pattern correction can be made to the mask, from no correction (FIG. 5A) to light (FIG. 5B) to heavy (FIG. 5C). FIG. 5C shows the addition of assisting features, which may be rim type features for a rim PSM mask.

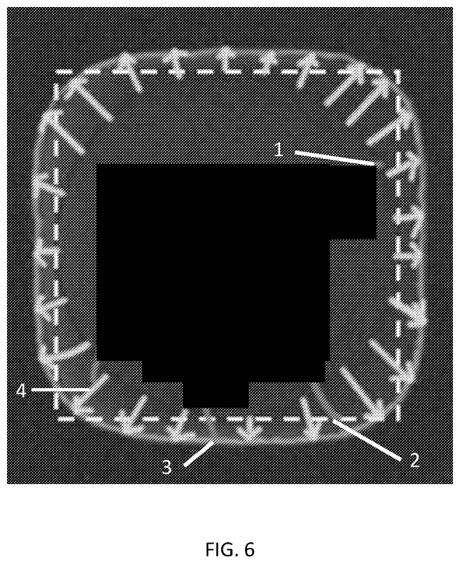

FIG. 6 shows components of skew driven mismatch between desired mask shape and desired feature. These mismatches get worse on a percent basis as the correction features get smaller as shown in the heavy OPC example in FIG. 5C. Specifically, rather than the desired rectangle or square shape, the mask expresses more of a rounded profile. The first rounding step is due to laser writing and developing and the second rounding step is due to an additional skew bias due to wet etching. In exemplary embodiments of the present invention, the first rounding step is fit with a Gaussian type model, and the second rounding step is fit with a contour propagation model.

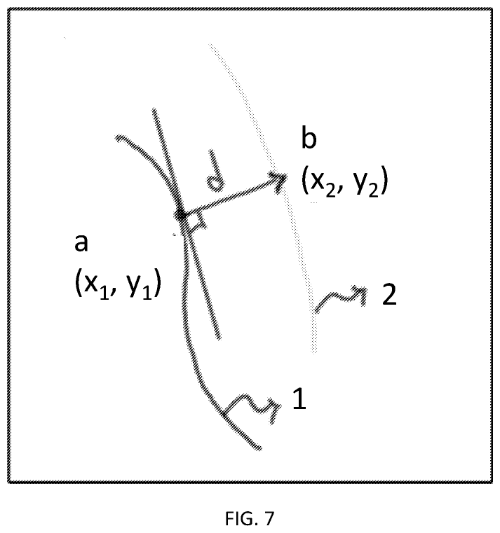

In embodiments, the skew model may be based on calculated point to point propagation vectors that bridge between the Gaussian type contour and real mask pattern contour with skew. The propagation vectors vary depending on etching skew of the material and process conditions. Thus, in embodiments, a different propagation vector model must be calculated for each combination of materials and conditions. More specifically, FIG. 7 shows the propagation vector d originating from a point a (X₁, Y₁) on the Gaussian type contour with a terminal point b (X₂, Y₂) on the real mask pattern contour resulting from the etching skew. In embodiments, the propagation vector extends in a 90 degree direction relative to the tangent of a point on the Gaussian type contour. In embodiments, the real mask pattern with skew can be contoured with, for example, so called descent, cell or ray trace type models, to name a few. A descent model will follow a high concentration of intensity to a lower level. In ray tracing, a line is drawn from the one contour to the next usually perpendicular to the first contour to create the next one. In embodiments, ray tracing is closest to a real wet etching application and is also very fast and easy to calculate. In cell models, more complicated directional vectors can be generated which consider the intensity in the cell and the direction of the previous contour indicated by a line perpendicular to the contour.

In embodiments, Element 1 involves the use of contour fitting using a Gaussian or similar type of smoothing model to represent the mask writing step and a second component for the wet etching that considers the contour propagation. By combining these components and feeding the result into the bias and OPC model of the mask correction tool, then a superior correction can be achieved as the physical mask process is now represented in the correction scheme.

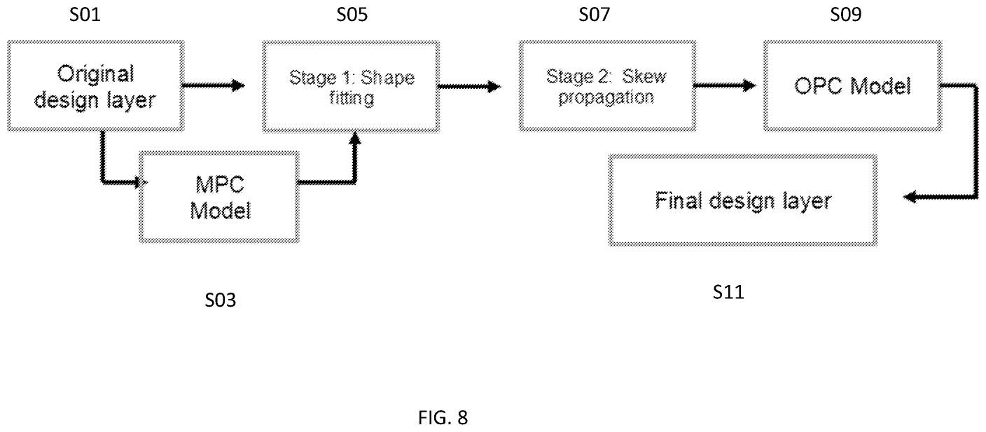

FIG. 8 shows a process for mask design correction in accordance with an exemplary embodiment of the present invention. In step S01 of the process, a mask correction tool may receive or otherwise obtain data associated with an original design layer, and in an optional step S03 perform mask process correction (MPC) to correct errors introduced during the mask making process. For example, the MPC may be used to correct mask making process effects such as fogging, development and etch loading and e-beam proximity effects.

In step S05, the mask correction tool takes the original design layer data and, optionally, the MPC data as input to a shape fitting algorithm to calculate a first contour resulting from laser writing and developing of the mask. The shape fitting algorithm may be based on a smoothing model, such as, for example, Gaussian contour fitting. More specifically, in exemplary embodiments, the shape fitting algorithm may be based on, for example, single or multiple, weighted overlapping Guassian models, circular morphology filters that average groupings of neighboring pixels, Lorentzian functions or in case of optical system an Airy disk function, to name a few.

In step S07, the mask correction tool takes the first contour determined in step S05 as input to an algorithm to calculate a second contour resulting from wet etching. In embodiments, the algorithm in step S07 may use data associated with etch properties and materials as further input to determine the propagation vectors extending from points on the contour determined in step S05. A series of propagation vectors may be calculated to determine the second contour, which represents the real mask pattern contour resulting from the etching skew.

In step S09, data associated with the second contour as calculated in step S07 is taken as input to an optical proximity correction model. The OPC model as modified based on the second contour data provides a more accurate correction scheme as compared to one that does not take into account the real contour resulting from etching skew. As a result, proximity corrected data associated with the final design layer can be presented in step S11 that will provide a more effective mask design.

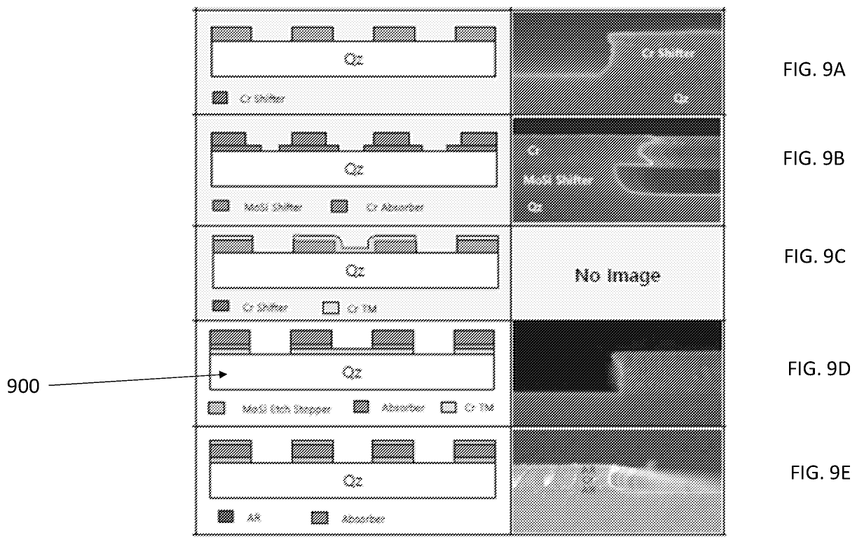

As discussed previously, in embodiments, Element 2 involves use of a mask making blank that minimizes the skew level with structural film compositions. In this regard, FIGS. 9A-9E show cross sections of several types of masks, including materials and stacking sequence. The cross-section profiles show different process bias and profiles which affect patterning in the panel lithography process. The images in particular show the skew level varies considerably between the different mask types.

In embodiments, in order the maximize the benefit of Element 1, it is highly advantageous to use a mask structure with lowest Stage 2 (e.g., wet etching) skew effect in cooperation with Element 1. In this regard, FIG. 9D shows a multi-layer film structure, generally designated by reference number 900, in accordance with an exemplary embodiment of the present invention. The film structure 900 is made up of three films of differing wet etching characteristics. In general, and in accordance with exemplary embodiments of the present invention, a low skew benefit is achieved with an N layer film stack, where N is greater than 2, with added low skew benefit as N is increased. In embodiments, the N layers may be multiple discrete base film materials or a single base film material with material modification into N effective layers during the base film deposition process. These films may be combined in any way to achieve a binary, phase shifting or multi-tone type mask.

In the specific example shown in FIG. 9D, the films are made up of two layers of Cr and one layer of MoSi disposed between the two layers of Cr. The bottom layer of Cr may or may not have a phase shifting property as this will not have a strong effect on the desired low skew property. The images in FIGS. 9B and 9D show the strong improvement in skew level achieved in accordance with exemplary embodiments of the present invention over the skew level of a two-layer film stack.

In embodiments, Element 1 may be combined with Element 2, thereby driving towards low skew so that mask pattern correction need not be overburdened to achieve a greater correction refinement.

As discussed previously, in embodiments, Element 3 involves use of a mask etching process that minimizes the skew level with process etching parameters. Specifically, in order to take advantage of the multiple films of Element 2, the steps in etching the films may also be optimized. Thus, in accordance with exemplary embodiments, the center film in a three-film stack serves as an etch stop layer and a second photomask coating is applied to and etched to minimize the final skew effect.

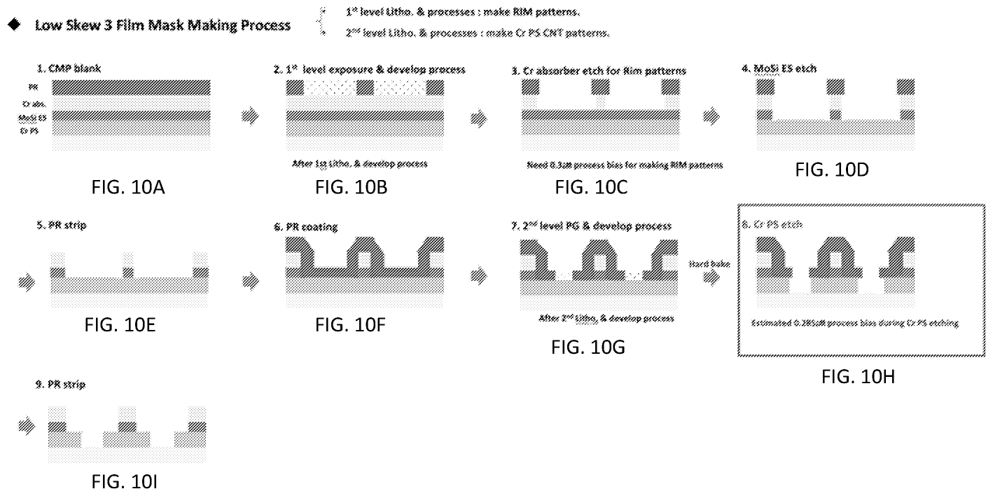

FIGS. 10A-10I illustrate a mask making flow in accordance with an exemplary embodiment of the present invention that minimizes the skew parameters in a three-film stack made up of MoSi and Cr layers. As shown in FIG. 10A, a mask blank is provided, with the blank made up of a substrate, a Cr phase shift layer disposed on top of the substrate, a MoSi etch stop layer disposed on top of the Cr phase shift layer, a Cr absorber layer disposed on top of the MoSi etch stop layer, and a first photoresist disposed on top of the Cr absorber layer. As shown in FIG. 10B, a first level exposure and development step results in removal of portions of the first photoresist, thereby exposing corresponding portions of the Cr absorbent layer. The exposed portions of the Cr absorber layer, as well as portions undercutting the first photoresist, are removed by an etching step (FIG. 10C), thereby exposing corresponding portions of the MoSi etch stop layer. The exposed portions of the MoSi etch stop layer are then etched away (FIG. 10D), thereby exposing corresponding portions of the Cr phase shifting layer, and the first photoresist is stripped (FIG. 10E). A second photoresist is then laid down on top of the Cr absorber layer, the MoSi etch stop layer and the exposed portions of the Cr phase shift layer (FIG. 10F). As shown in FIG. 10G, a second level exposure and development step results in removal of portions of the second photoresist, thereby again exposing corresponding portions of the Cr phase shift layer. The exposed portions of the Cr phase shift layer, as well as portions undercutting the second photoresist, are removed by an etching step (FIG. 10H), thereby exposing corresponding portions of underlying substrate. The second photoresist is then stripped (FIG. 10I). In this case, the center MoSi serves as an etch stop layer and the second photomask coating is applied and etched to minimize the final skew effect.

While in the foregoing specification a detailed description of a specific embodiment of the invention was set forth, it will be understood that many of the details herein given may be varied considerably by those skilled in the art without departing from the spirit and scope of the invention.

1. A method of manufacturing a photomask, comprising:
receiving initial photomask design data associated with one or more patterns to be formed on a photomask;
determining based on the initial photomask design data a first contour associated with at least one of the one or more patterns expected to result from writing of the photomask;
determining based on the first contour a second contour associated with the at least one of the one or more patterns expected to result from etching of the written photomask, where the second contour is an expected actual contour of the at least one of the one or more patterns;
performing, using the second contour associated with the at least one of the one or more patterns, optical proximity correction to the initial photomask data; and
generating corrected photomask design data based on the optical proximity corrected initial photomask design data.

2. The method of claim 1, wherein the step of determining a first contour is performed using a smoothing model.

3. The method of claim 2, wherein the smoothing model is a Gaussian model.

4. The method of claim 1, wherein the step of determining a second contour is performed by determining propagation vectors extending from the first contour.

5. The method of claim 4, wherein the propagation vectors are based on at least one of etch skew and etch process parameters.

6. The method of claim 1, further comprising the step of providing a mask blank comprising at least three layers disposed over a substrate.

7. The method of claim 1, further comprising the step of processing the mask blank using the corrected photomask design data to form a photomask for use in a lithography process.

8. The method of claim 7, wherein the photomask is a large-size photomask for use in a lithography process to manufacture a flat panel display (FPD).

9. The method of claim 8, wherein the photomask blank comprises:
a substrate;
a first layer disposed over the substrate that is a phase shift layer;
a second layer disposed over the first layer that is an etch stop layer; and
a third layer disposed over the second layer that is an absorber layer.

10. The method of claim 9, wherein the step of processing the mask blank comprises:
exposing and developing a first photoresist disposed over the third layer so as form a pattern of exposed portions of the third layer;
etching the exposed portions of the third layer so as to form a pattern of exposed portions of the second layer;
etching the exposed portions of the second layer so as to form a pattern of exposed portions of the first layer;
depositing a second photoresist over the first layer, the etched second layer, and the etched third layer;
exposing and developing the second photoresist so as to form a pattern of exposed portions of the first layer; and
etching the exposed portions of the first layer so as to form a pattern of exposed portions of the substrate.

11. The method of claim 9, wherein the first layer comprises Cr.

12. The method of claim 9, wherein the second layer comprise MoSi.

13. The method of claim 9, wherein the third layer comprises Cr.

14. A method of manufacturing a photomask, comprising two or more of the following steps (A), (B) and (C):
(A) generating a photomask pattern design, the step of generating comprising:
(1) receiving initial photomask design data associated with one or more patterns to be formed on a photomask;
(2) determining based on the initial photomask design data a first contour associated with at least one of the one or more patterns expected to result from writing of the photomask;
(3) determining based on the first contour a second contour associated with the at least one of the one or more patterns expected to result from etching of the written photomask, where the second contour is an expected actual contour of the at least one of the one or more patterns;
(4) performing, using the second contour associated with the at least one of the one or more patterns, optical proximity correction to the initial photomask data; and
(5) generating corrected photomask design data based on the optical proximity corrected initial photomask design data;
(B) providing a mask blank comprising at least three layers disposed over a substrate; and
(C) processing a mask blank comprising a substrate, a first layer disposed over the substrate that is a phase shift layer, a second layer disposed over the first layer that is an etch stop layer, and a third layer disposed over the second layer that is an absorber layer, the step of processing comprising:
(1) exposing and developing a first photoresist disposed over a third layer so as form a pattern of exposed portions of the third layer;
(2) etching the exposed portions of the third layer so as to form a pattern of exposed portions of the second layer;
(3) etching the exposed portions of the second layer so as to form a pattern of exposed portions of the first layer;
(4) depositing a second photoresist over the first layer, the etched second layer, and the etched third layer;
(5) exposing and developing the second photoresist so as to form a pattern of exposed portions of the first layer; and
(6) etching the exposed portions of the first layer so as to form a pattern of exposed portions of the substrate.

15. The method of claim 14, wherein the method comprises steps (A) and (B).

16. The method of claim 14, wherein the method comprises steps (A), (B) and (C).

17. The method of claim 14, wherein the photomask is a large-size photomask for use in a lithography process to manufacture a flat-panel display (FPD).

18. A method of making a flat panel display comprising irradiating light from an optical energy source through a large-size photomask made in accordance with the method of claim 14 and onto a glass plate substrate in a photolithographic process so that the at least one circuit pattern is transferred from the large-size photomask to the glass plate substrate.

19. The method of claim 18, wherein the flat-panel display is a liquid crystal display, an active matrix liquid crystal display, an organic light emission diode, a light emitting diode, a plasma display panel, or an active matrix organic light emission diode.
